(19) United States
(12) Patent Application Publication
(10) Pub. No.: US 2014/0179038 A1
(43) Pub. Date: Jun. 26, 2014

(54) METHOD FOR MANUFCTURING LIGHT EMITTING DIODE PACKAGE

(71) Applicant: Hon Hai Precision Industry Co., Ltd., New Taipei (TW)

(72) Inventor: CHIH-CHEN LAI, New Taipei (TW)

(21) Appl. No.: 13/923,292

(22) Filed: Jun. 20, 2013

(30) Foreign Application Priority Data
Dec. 26, 2012 (TW) 101150012

(51) Int. Cl. H01L 33/52

(52) U.S. Cl. CPC H01L 33/52
USPC 438/27

(57) ABSTRACT

A method for manufacturing an LED package comprising following steps: providing a substrate and an LED chip mounted on the substrate; providing glue and arranging the glue on a periphery of the substrate and drying the glue to form a blocking loop to enclose the LED chip therein; and injecting the glue in the blocking loop, and drying the glue to form a packaging layer to encapsulate the LED chip therein. Light emitted from the LED chip travels through a top surface of the packaging layer, a periphery of the packaging layer, and the blocking loop to illuminate.

### BACKGROUND

1. Technical Field

The present disclosure relates to semiconductor devices and, more particularly, to a light emitting diode (LED) package.

2. Description of Related Art

Referring to FIGS. 1-3, a method for manufacturing an LED package includes following steps: providing a substrate 100 and an LED chip 200 mounted on the substrate 100; providing glue 300 and arranging the glue 300 on a periphery of the substrate 100 to enclose the LED chip 200 therein; providing a blocking member 400 and fixing the blocking member 400 on the glue 300; filling the glue 300 in the blocking member 400 to form a packaging layer 500 to encapsulate the LED chip 200 therein.

However, the blocking member 400 is opaque and blocks light emitted from the LED chip 200 traveling through a periphery of the LED package. Thus, the light at a periphery of the LED package is relatively poor and typically cannot be used to illuminate. Therefore the LED package cannot be used in a lamp which requires a wide illumination range.

Accordingly, it is desirable to provide a method for manufacturing the LED package which can overcome the described limitations.

### BRIEF DESCRIPTION OF THE DRAWINGS

FIGS. 1-3 show steps for manufacturing a conventional LED package.

FIGS. 4-6 show steps for manufacturing an LED package of the present disclosure.

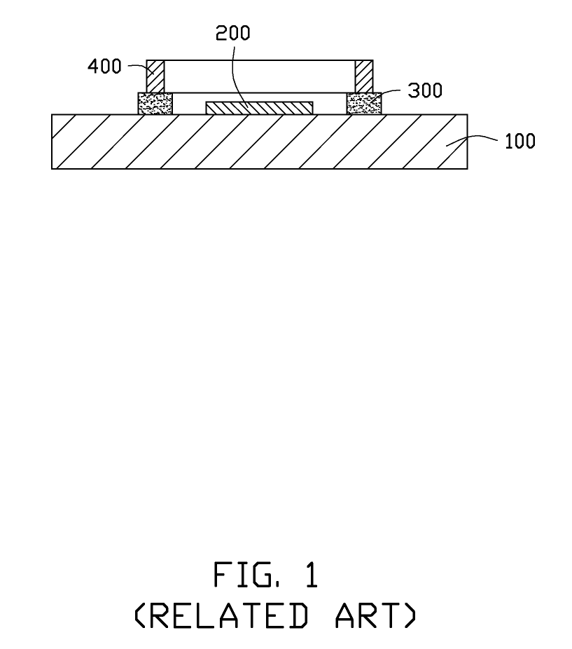

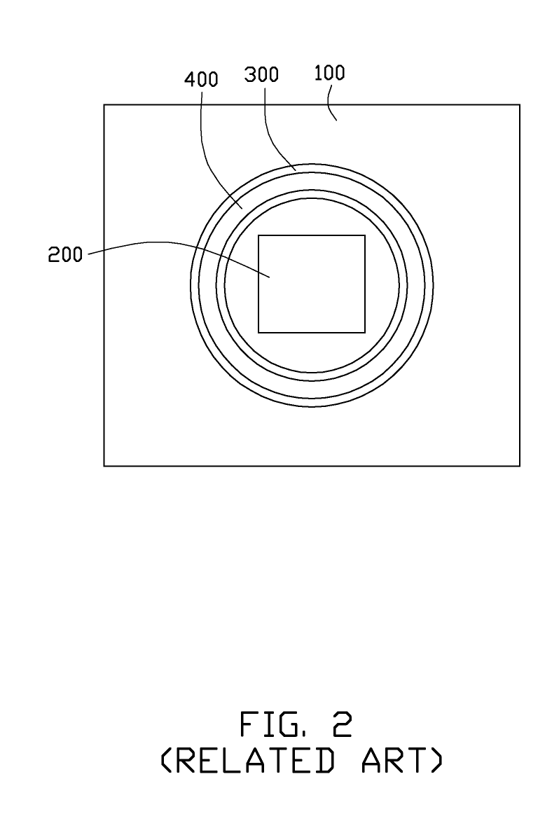

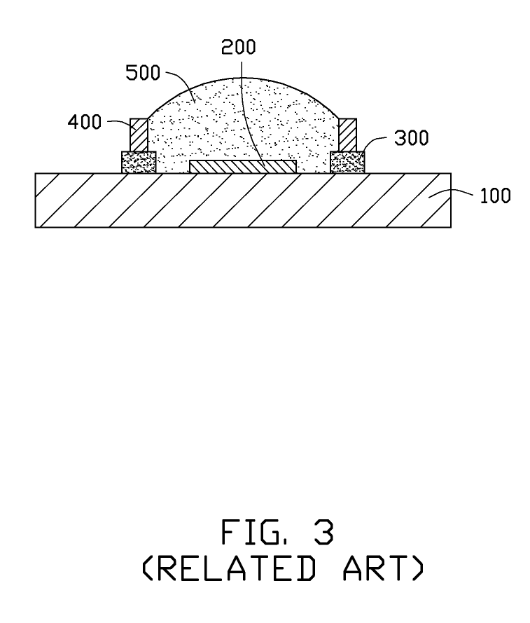

### DETAILED DESCRIPTION

Embodiments of a method for manufacturing the LED package will now be described in detail below and with reference to the drawings.

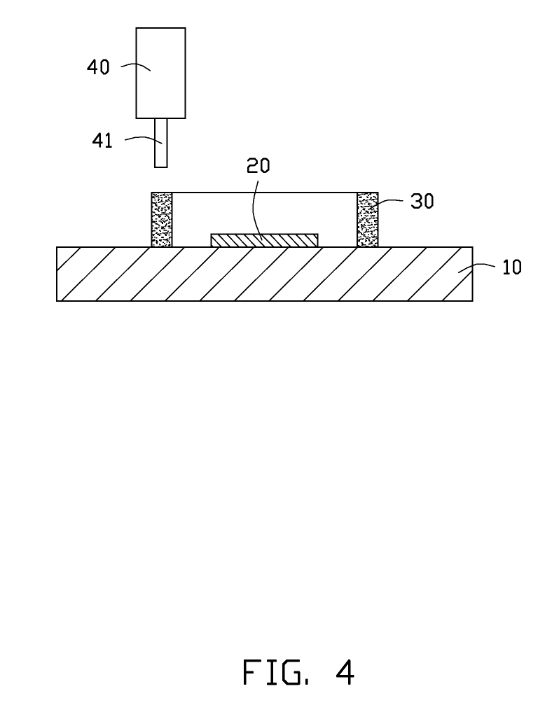

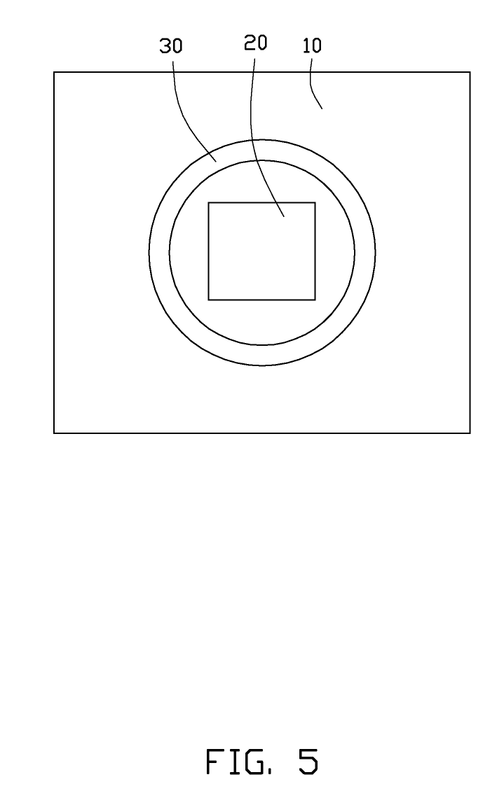

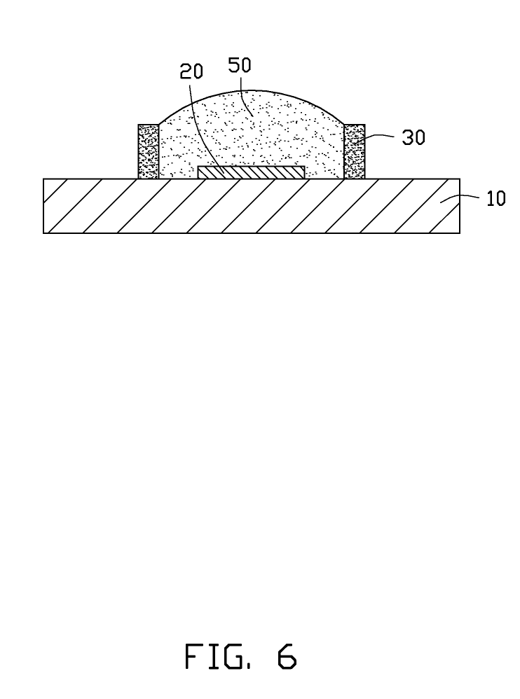

Referring to FIGS. 4-6, a method for manufacturing an LED package includes following steps:

The first step is providing a substrate 10, forming a circuit (not shown) on a top surface of the substrate 10, and an LED chip 20 mounted on the substrate 10 and electrically connecting circuit on the substrate 10. In this embodiment, the substrate 10 is made of material having good heat dissipation performance and being electrically insulating, for example, sapphire.

The second step is providing a dispensing machine 40 with a nozzle 41, providing glue, and filling the glue in the dispensing machine 40. The glue is a mixture mixed by a pure optical encapsulant material and phosphor powder. The glue is squeezed out the dispensing machine 40 from the nozzle 41.

The third step is squeezing the glue out the dispensing machine 40, arranging the glue on a periphery of the substrate 10 and drying the glue to form a blocking loop 30 to enclose the LED chip 20 therein. A size of the blocking loop 30 may be adjusted to control a density of the glue, and a squeezed out quantity of the glue.

The fourth step is injecting the glue in the blocking loop 30, and drying the glue to form a packaging layer 50 to encapsulate the LED chip 20 therein. A top surface of the packaging layer 50 is convex and has a lower end thereof directly contacting a top end of the blocking loop 30, the top surface extends upwardly beyond the top end of the blocking loop 30 except the lower end of the top surface. Light emitted from the LED chip 20 travels through the top surface of the packaging layer 50, a periphery of the packaging layer 50, and the blocking loop 30 to illuminate. Thus, the LED package has a wide illumination range.

The glue may be diluted before injected in the blocking loop 30, thus, the quantity of the glue will be decreased. Therefore, a cost for manufacturing the LED package will be decreased.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing an LED package comprising following steps:
providing a substrate and an LED chip mounted on the substrate;
providing a dispensing machine with a nozzle, and filling the dispensing machine with glue;
squeezing the glue out of the dispensing machine from the nozzle, arranging the glue on a periphery of the substrate and drying the glue to form a blocking loop to enclose the LED chip therein; and
injecting the glue in the blocking loop, and drying the glue to form a packaging layer to encapsulate the LED chip therein;
wherein light emitted from the LED chip travels through a top surface of the packaging layer, a periphery of the packaging layer, and the blocking loop to illuminate.

2. The method of claim 1, wherein the glue is a mixture mixed by a pure optical encapsulant material and phosphor powder.

3. The method of claim 1, wherein the glue is diluted before injected in the blocking loop.

4. The method of claim 1, wherein a top surface of the packaging layer is convex and beyond a top end of the blocking loop.

5. A method for manufacturing an LED package comprising following steps:
providing a substrate and an LED chip mounted on the substrate;
providing glue and arranging the glue on a periphery of the substrate and drying the glue to form a blocking loop to enclose the LED chip therein; and
injecting the glue in the blocking loop, and drying the glue to form a packaging layer to encapsulate the LED chip therein;
wherein light emitted from the LED chip travels through a top surface of the packaging layer, a periphery of the packaging layer, and the blocking loop to illuminate.

6. The method of claim 5 further comprising a step for providing a dispensing machine with a nozzle, the glue is filled in the dispensing machine and squeezed out the dispensing machine from the nozzle.

7. The method of claim 5, wherein the glue is diluted before injected in the blocking loop.

8. The method of claim 5, wherein the glue is a mixture mixed by a pure optical encapsulant material and phosphor powder.
